(19) United States
(12) Patent Application Publication
(10) Pub. No.: US 2024/0383683 A1
(43) Pub. Date: Nov. 21, 2024

(54) System and Method for the Storage and Picking of Materials

(71) Applicant: Essegi Automation S.R.L., Sovizzo (VI) (IT)

(72) Inventor: Matteo Padoan, Sovizzo (IT)

(21) Appl. No.: 18/693,427

(22) PCT Filed: Nov. 8, 2022
(86) PCT No.: PCT/IB2022/060738

§ 371 Date: Mar. 19, 2024

(30) Foreign Application Priority Data
Nov. 9, 2021 (IT) 102021000028454

(51) Int. Cl. B65G 1/137

(52) U.S. Cl. CPC B65G 1/137; B65G 2201/0258

(57) ABSTRACT

A system for the storage and picking of coils arranged on trays housed in an accumulation structure includes a plurality of walls defining a vertical direction and which are spaced apart, facing each other and aligned one after the other along a horizontal direction orthogonal to the vertical direction. Between the walls there is included a plurality of accommodation spaces superimposed and spaced apart one after the other according to the vertical direction and delimited at the walls by a guide that defines a transverse direction of insertion/extraction of the trays in/from the aforesaid accommodation spaces. The transverse direction is orthogonal to the frontal plane of the accumulation structure. The depth of the accommodation spaces is at least the same as the length of two or more trays which are coplanar with each other when the trays are arranged aligned with each other one after the other within a respective accommodation space.

### BACKGROUND OF THE INVENTION

### 1. The Field of the Invention

The invention concerns a system for the storage and picking of materials, particularly but not exclusively for the storage and picking of mainly flat elements with limited thickness.

The invention also concerns a method for the storage and picking of materials using the aforesaid system.

### 2. The Relevant Technology

The use of the system and of the method that uses the aforesaid system is particularly aimed at companies operating in the field of assembly of electronic boards and is used for the storage and picking of coils of flexible tapes to which electronic components of the SMD (Surface Montage Devices) type are removably applied.

As is known, the assembly of electronic boards is carried out by using automatic machines in which special motorized arms equipped with grippers pick the electronic components to be assembled which are removably associated with a flexible tape wound on a coil and apply them to a rigid support, for example a printed circuit.

The coils are housed in quadrangular trays that are kept in a system comprising one or more magazines in each of which there is an accumulation structure that accommodates the trays.

If necessary, the trays are extracted from the accumulation structure and the coils are picked to use, at the time of assembly, the electronic components arranged on them.

After use, the coils with the remaining electronic components are placed back on the respective trays that are introduced again into the accumulation structure.

By way of example, FIG. 1 shows an axonometric view of a magazine of the prior art, indicated overall with A, in which there is an accumulation structure B comprising a plurality of vertical walls C facing and spaced apart from each other and also visible in the detail of FIG. 2 and in the plan view of FIG. 3, which are provided with projections D.

In this way, each pair of projections D which are opposite each other defines a housing E (aka “accommodation space”) that accommodates a tray F on which a coil G is housed with a wound flexible tape with the electronic components removably associated with it.

As can be seen in the Figures, the accumulation structure B comprises a plurality of housings E and is therefore able to accommodate an equal number of trays F that are arranged side by side one another according to a horizontal direction X and are superimposed on each other according to a vertical direction Z.

As mentioned, if necessary, one or more trays F are picked up in succession from the respective housings E and the coil G that each tray F supports is picked up by an operator and loaded onto the board assembly machine that detaches the components to be assembled from the tape of the coil G.

At the end of assembly, the coils G that have not been fully used are unloaded from the machine and the operator places them again in the respective trays F and these are placed in the respective housings E of the accumulation structure B.

The picking/re-placing of the trays F from/into the accumulation structure B is carried out using automatic handling systems H controlled by a software that manages the reading of the identification codes of the trays F and their positioning in the housings E.

Since each housing E of the accumulation structure B houses a single tray F which in turn houses a single coil B, there is a code on the coil but not on the tray and the machine identifies the type of tray to which it autonomously matches the code of the coil itself.

The management software thus associates this code with the position that the tray and the relative coil will assume in the accumulation structure B.

This ensures that the coil the operator picks up from the tray being extracted is precisely the one chosen by the management software.

Therefore, the possibility of the operator picking up the wrong coil is essentially ruled out.

In order to increase the accumulation capacity of the magazines for the same number of housings present in the accumulation structure, embodiments are known in which a tray supporting two or more coils is accommodated in each housing.

This, advantageously, significantly increases the amount of coils that are stored but may lead to errors in the storage and picking of coils caused unintentionally by the operator who performs these operations.

In fact, in the magazines of this type, the software manages the storage and the picking of the trays according to their code and when a tray is extracted from the respective housing, it is the operator who chooses which coil to pick among those present on the tray itself.

Obviously, the operator acts on the basis of a picking list on which the identification codes of the coils to be picked up that are printed on the coils are shown, but this does not prevent the operator from picking up one or more wrong coils due to inattention or a trivial reading error.

If this happens, damaging downtimes or incorrect component assemblies on the boards can occur, thus resulting in the production of discarded boards.

### SUMMARY OF THE INVENTION

The present invention intends to overcome the drawbacks that have been complained of.

To this end, a first aim is to realize a system for the storage and picking of materials, preferably of trays that support tape coils on which electronic components are removably fixed, which allows greater reliability in picking the coils than known equivalent systems.

It is therefore wished to realize a system that substantially rules out the possibility of the operator making mistakes when picking/positioning the coils from/on the respective trays.

Another aim is to realize a method for the storage and picking of the trays in/from the respective magazine that uses the aforesaid system.

The aforesaid aims are achieved by the system having the characteristics according to the main claim, to which reference will be made, and by the method according to the claims that use said system.

Advantageously, the system and the method of the invention simplify the management of picking/storing the trays and the relative coils with respect to the prior art systems and also make it more reliable than the equivalent known systems.

### BRIEF DESCRIPTION OF THE DRAWINGS

The listed objects and advantages and any others will be better highlighted below during the description of a preferred but not exclusive embodiment of the system and of the method of the invention which is given by way of non-limiting example with reference to the attached drawing tables in which:

FIG. 1 represents a sectional axonometric view of a prior art system for the storage and picking of materials, particularly of mainly flat elements with small thickness;

FIG. 2 represents an enlarged detail of FIG. 1;

FIG. 3 represents a plan view of FIG. 1;

FIG. 4 represents the front view of the system of the invention;

FIG. 5 represents the sectional view according to plane V-V of the system of the invention represented in FIG. 4;

FIG. 6 represents the sectional view according to plane VI-VI of the system of the invention represented in FIG. 4;

FIG. 7 represents in axonometric view an enlarged detail of FIG. 5;

FIGS. 8 to 28 represent the sectional plan view of the system of the invention represented in FIG. 5 in different operating positions.

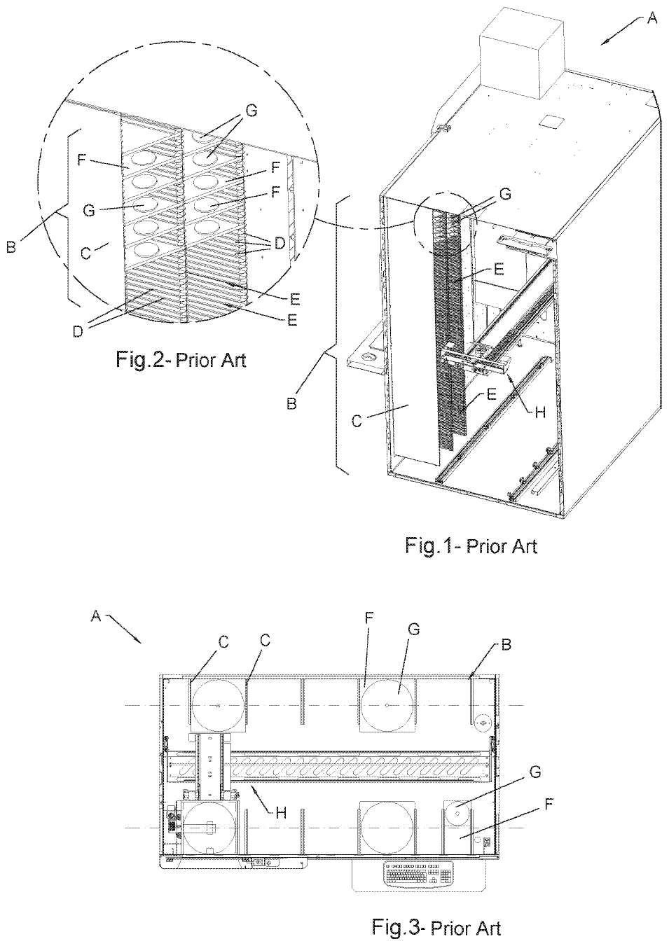

### DETAILED DESCRIPTION OF THE PREFERRED EMBODIMENTS

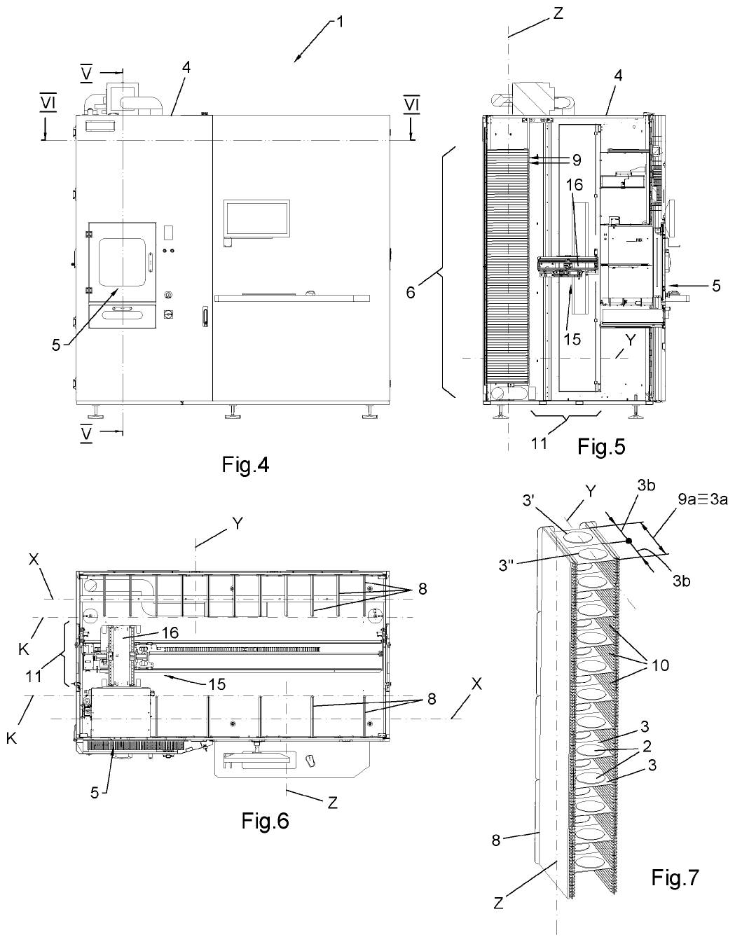

The system for the storage and picking of materials subject-matter of the invention is depicted in different views in FIGS. 4 to 6, where it is indicated overall with 1.

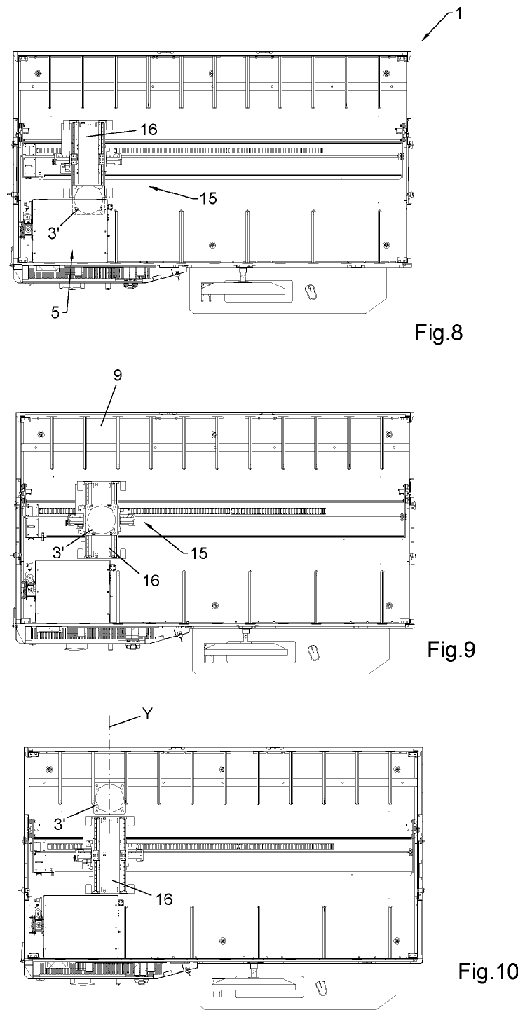

Furthermore, a detail of the system of the invention and particularly a detail of FIG. 5 is depicted in FIG. 7, and FIGS. 8 to 28 represent the sectional plan view of the system of the invention in different operating steps that will be described later.

The system 1 of the invention is used for the storage and picking of objects 2 with limited thickness arranged on trays 3.

In the following description reference will be made to a system 1 in which on the trays 3 coils 2 are placed on which a flexible tape is wound to which electronic components are removably fixed for use in electronic board assembly machines.

Obviously, the system 1 of the invention can still be used for the storage and picking of any other object or material with small thickness and adapted to be placed on a tray 3.

It can be noted that the system 1 comprises a containment structure 4, provided with at least one door 5 communicating with the external environment and accessible to an operator, for the insertion and extraction of the trays 3 in/from an accumulation structure 6 which is enclosed in the containment structure 4.

The accumulation structure 6 is therefore in communication with the external environment through the door 5 and comprises a plurality of walls 8 arranged vertically and therefore according to a vertical direction Z that they define, wherein the aforesaid walls 8 are spaced apart, facing each other and aligned one after the other along a horizontal direction X orthogonal to the vertical direction Z.

Between the walls 8 facing each other there is included a plurality of accommodation spaces 9 that are superimposed and spaced apart one after the other according to the vertical direction Z and that are delimited at the walls 8 by guide means 10 that define for each accommodation space 9 a transverse direction Y of insertion/extraction of the trays 3.

The transverse direction Y, as can be seen particularly in FIG. 6, is orthogonal to the frontal plane K of the accumulation structure 6 which is parallel to the horizontal direction X highlighted in FIG. 6 and to the vertical direction Z highlighted in FIGS. 5 and 7.

There are also means 11 for moving the trays 3 with the coils 2 arranged on them that move the aforesaid trays 3 displacing them among the accommodation spaces 9, or from the door 5 present on the containment structure 4 to the accommodation spaces 9 or even from the accommodation spaces 9 to the door 5.

According to the invention, in the system 1 the depth 9a of the accommodation spaces 9 measured according to the transverse direction Y is at least the same as the length 3a of two or more of said trays 3 which are coplanar with each other when the trays 3 are arranged aligned with each other one after the other within a respective accommodation space 9.

In the system 1 of the invention, in each accommodation space 9 two or more trays 3 arranged aligned with each other one after the other can therefore be accommodated, but in the preferred embodiment described herein two trays 3 are accommodated in each accommodation space 9 and the depth 9a of the accommodation spaces 9, measured according to the transverse direction Y, is therefore the same as the overall length 3a of two trays 3 coplanar with each other and arranged aligned with each other one after the other within a respective accommodation space 9.

In particular, the system 1 of the invention uses trays 3 all having the same length 3b so that the overall length 3a of two trays 3 that are aligned with each other is the same as the depth 9a of each accommodation space 9.

Basically, trays 3 are used, the length 3b of each of which is equal to half the depth 9a of each accommodation space 9.

Advantageously with respect to the known systems described in which each housing accommodates a tray that supports a coil, the system 1 of the invention allows to reduce the number of accommodation spaces 9 to be managed with the same number of trays 3 housed.

Furthermore, advantageously with respect to the known systems described in which each housing accommodates a tray with two coils arranged thereon, the system 1 of the invention allows to almost totally eliminate the possibility of the operator choosing the wrong coil 2, since each tray 3 accommodates only one coil 2.

In summary, the system 1 of the invention has all the advantages of the disclosed known systems, but not their drawbacks and defects.

With regard to the guide means 10, they comprise a plurality of shaped channels that are present on the surfaces facing each other of the walls 8 and that develop according to the transverse direction Y, as can be seen in particular in FIGS. 5 and 7.

In particular, the height of each shaped channel, measured according to the vertical direction Z, is slightly higher than the thickness of each tray 3 so that each tray 3 can slide freely without interference in the respective shaped channel.

As regards the movement means 11, it can be noted in the figures that they comprise a Cartesian robot 15 arranged inside the accumulation structure 6 and configured to slide parallel to the frontal plane K, which comprises displacement and gripping means 16 that are configured to move the trays 3 inside the same accumulation structure 6.

In particular, the displacement and gripping means 16 are configured:
to transfer the trays 3 with the objects 2 present thereon among the accommodation spaces 9;
to transfer each tray 3 with the objects 2 arranged thereon from the door 5 into any one of the accommodation spaces 9 and to transfer each tray 3 with the objects 2 arranged thereon from any accommodation space 9 to the door 5.

There are also computer means comprising memory means in which a computer product is stored which, when it is in the processing step, manages and controls the system 1.

The method for the storage and picking of the coils 2 arranged on the respective trays 3 by using the system 1 just described envisages:
that the storage of the coils 2 takes place by slidingly inserting into each accommodation space 9 at least two trays 3 arranged aligned one after the other according to the transverse direction Y, wherein in each accommodation space 9 the introduction of the first tray 3′ is followed by the introduction of at least a second tray 3″ which is pushed against the first tray 3′ so that both trays 3′, 3″ advance towards the bottom of the accommodation space 9 according to the transverse direction Y;
that the picking of the coils 2 takes place by extracting the trays 3′; 3″ one after the other from the respective accommodation space 9 in which they are housed, where the extraction of the first tray 3′, which is the one arranged in a position closest to the bottom of the accommodation space 9, takes place after extracting at least a second tray 3″ preceding the first tray 3′ and that is inserted into an auxiliary accommodation space 9′ before proceeding to extract the first tray 3′ of the accommodation space 9.

In particular, the method for storage that has just been briefly described is now described by listing and describing, with reference to FIGS. 8 to 13, each of the operations that compose it.

It should be noted that the method is described and represented herein with reference to a situation in which only two trays 3, particularly a first tray 3′ and a second tray 3″, are stored aligned and coplanar one after the other according to the transverse direction Y within a respective accommodation space 9 of the accumulation structure 6. It is specified that this is just an exemplary embodiment for describing the method for storage which may be referred to even more than two trays aligned with each other and housed in the same accommodation space 9.

Having made this necessary premise, it can be noted that FIG. 8 depicts the displacement and gripping means 16 of the Cartesian robot 15 that pick the first tray 3′ to be stored at the door 5 present in the containment structure 4.

The displacement and gripping means 16 then place the first tray 3′ aligned and coplanar frontally to a chosen accommodation space 9 as can be seen in FIG. 9, and insert it into the chosen accommodation space 9 by making it advance by sliding towards the bottom according to the transverse direction Y until it is placed in the position as can be seen in FIG. 10.

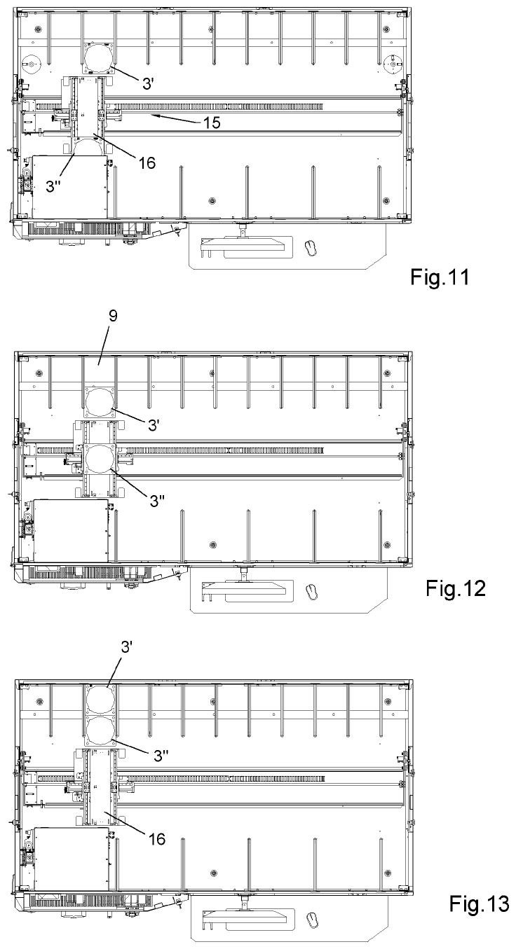

The displacement and gripping means 16 of the Cartesian robot 15 then pick a second tray 3″ as can be seen in FIG. 11, and place it aligned and coplanar with the chosen accommodation space 9 and with the first tray 3′, as can be seen in FIG. 12.

The displacement and gripping means 16 then place the second tray 3″ in contact with the first tray 3′ already inserted into the chosen accommodation space 9 and then push the second tray 3″ against the first tray 3′ to advance and insert both into the chosen accommodation space 9 by sliding according to the transverse direction Y and towards the bottom of the same chosen accommodation space 9, as can be seen in FIG. 13.

In another embodiment of the accumulation structure having deeper accommodation spaces, the operations depicted in FIGS. 11 to 13 may be repeated for inserting any other trays into the same accommodation space, or into the system 1 of the invention, the operations 8 to 13 may be repeated for accommodating additional pairs of trays 3′, 3″ in another accommodation space 9.

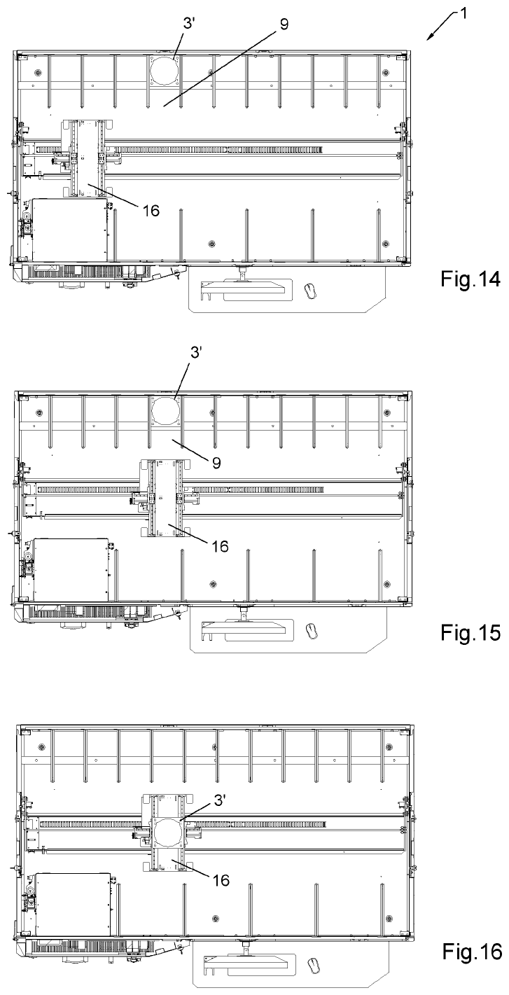

The trays present in the accumulation structure 6 are picked at the user's discretion by means of the method for picking that has already been synthetically described and which comprises a plurality of operations that are described below with reference to FIGS. 14 to 28, starting from the situation represented in FIG. 14 in which in the accommodation space 9 there is only a first tray 3′.

In this case, the first tray 3′ to be picked is immediately accessible and can be picked by the displacement and gripping means 16 which are placed aligned with the accommodation space 9 as can be seen in FIG. 15 and which extract it by placing it as can be seen in FIG. 16.

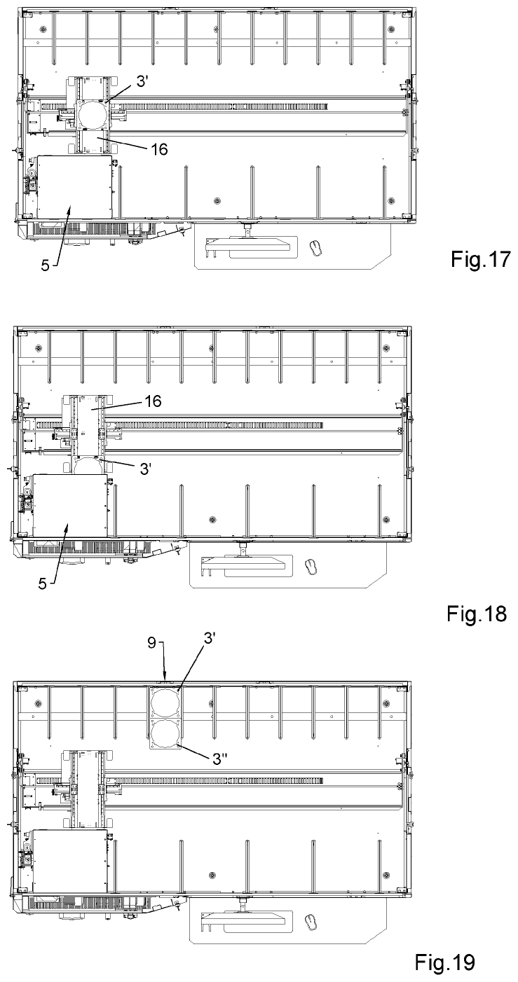

The first tray 3′ is then carried at the door 5 as can be seen in FIG. 17, in a position suitable for it to be extracted from the aforesaid door 5 as can be seen in FIG. 18. If instead in the accommodation space 9 there are a first tray 3′ and a second tray 3″ aligned with each other as can be seen in FIG. 19, and if the user is interested in extracting the second tray 3″ which, again in this case, is immediately accessible, the extraction takes place in exactly the same way as just described.

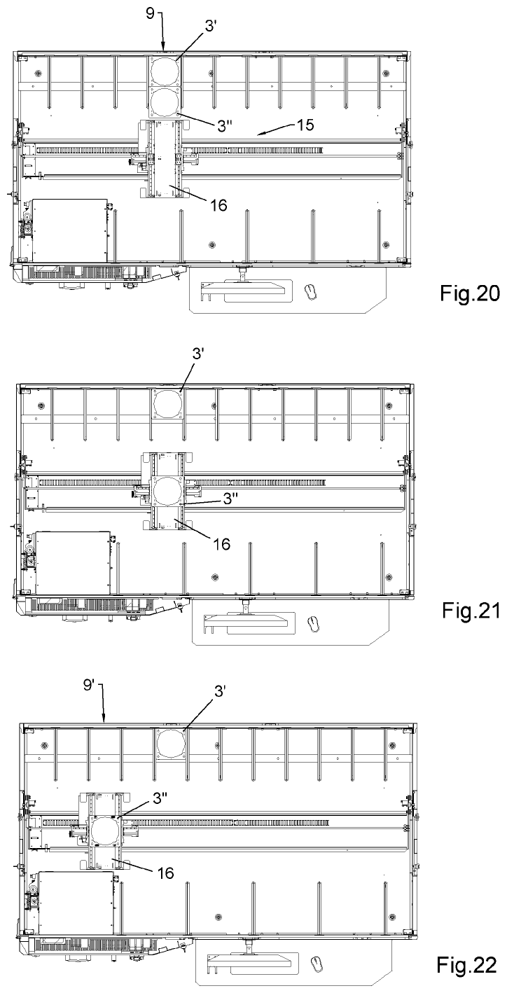

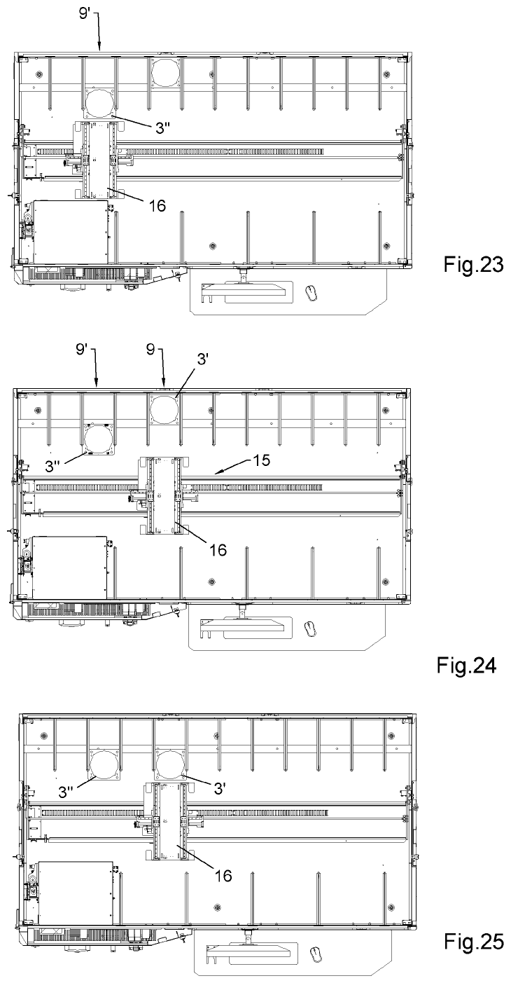

If, on the other hand, the tray that the user is interested in extracting is the first tray 3′, the Cartesian robot 15 places the displacement and gripping means 16 aligned with the accommodation space 9 as can be seen in FIG. 20, which extract the second tray 3″ as can be seen in FIG. 21, carry it at an auxiliary accommodation space 9′ as can be seen in FIG. 22, into which they insert it as can be seen in FIG. 23.

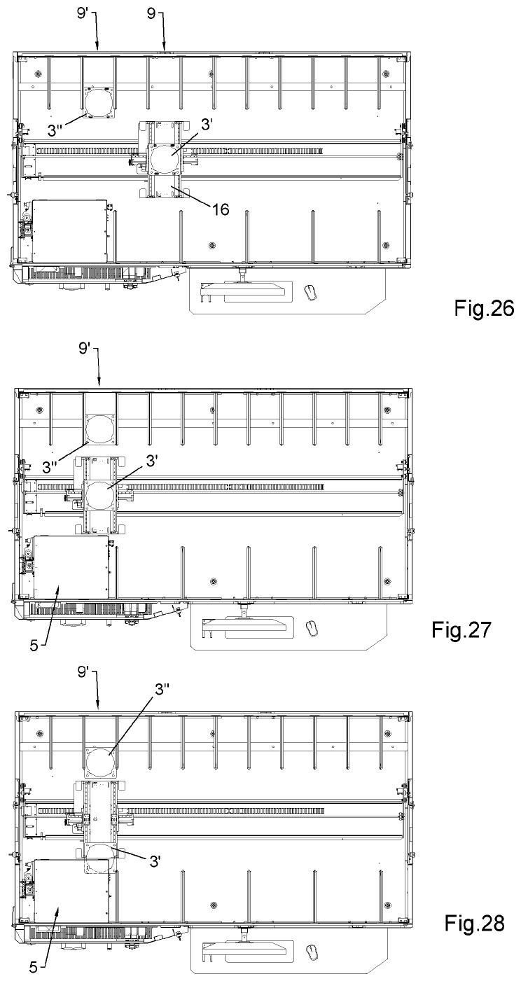

At this point, the Cartesian robot 15 places the displacement and gripping means 16 aligned again with the accommodation space 9 as can be seen in FIG. 24, which pick the first tray 3′ as can be seen in FIGS. 25 and 26, and displace it as can be seen in FIG. 27 up to the door 5, through which they pick it as can be seen in FIG. 28.

All the movements are managed by the computer means that control all the displacements of the trays 3′ and 3″ and therefore of the relative coils 2 that they support to ensure their traceability within the accommodation spaces 9 and 9′.

Obviously, the computer means will also be able to manage movements other than those described, which may include, for example, movements of the trays among the accommodation spaces to defragment the volume of the accumulation structure 6 or for other purposes.

Based on what is described, it is understood that the system and the method of the invention achieve the set objects and advantages.

The description has highlighted that the system and the method for storage and picking, subject-matter of the invention, allow greater reliability in the picking and storage of the coils compared to the known systems equivalent to them, since they substantially exclude the possibility of the operator being able to make errors in picking/positioning the coils from/onto the respective trays.

The description has also highlighted that the system of the invention, in comparison with the known systems described in which each housing accommodates a tray that supports a coil, advantageously allows to reduce the number of accommodation spaces to be managed with the same number of housed trays.

The description has also highlighted that the system of the invention, in comparison with the known systems described in which each housing accommodates a tray with two coils arranged thereon, allows to almost totally eliminate the possibility of the operator choosing the wrong coil, since each tray houses just one coil.

In summary, as already stated in the description, the system of the invention has all the advantages of the disclosed known systems, but not their drawbacks and defects.

In the execution step, modifications and variations not described and not represented in the figures may be made to the system and the method of the invention.

However, such modifications and variations, if they fall within the scope of the following claims, must all be considered protected by the present invention.

1. A system for the storage and picking of objects arranged on trays comprising:
a plurality of said trays, each configured to house one or more of said objects and each having a predefined length, said length being the same for all said trays;
a containment structure for an accumulation structure of said plurality of said trays with said objects, said containment structure being provided with at least one door communicating with the external environment and with said accumulation structure for the insertion/extraction of said trays with said objects in/from said accumulation structure, said accumulation structure comprising:
a plurality of walls defining a vertical direction, said walls being spaced apart, facing each other and aligned one after the other along a horizontal direction orthogonal to said vertical direction;
a plurality of accommodation spaces comprised between said walls facing each other, said accommodation spaces being superimposed and spaced apart one after the other according to said vertical direction and being delimited at said walls by guide means which are configured to define a transverse direction of insertion/extraction of said trays with said objects in/from said accommodation spaces, said transverse direction being orthogonal to the frontal plane of said accumulation structure, said frontal plane being parallel to said horizontal direction and to said vertical direction, wherein the depth of said accommodation spaces measured according to said transverse direction is at least equal to twice said length of each of said trays and therefore at least the same as the length of two of said trays which are coplanar with each other when said trays are arranged aligned with each other one after the other within a respective accommodation space;
movement means configured to move said trays with said objects:
between said accommodation spaces;
from said door to said accommodation spaces;
from said accommodation spaces to said door,
wherein said movement means are configured to:
slidingly insert into said accommodation spaces at least two trays arranged aligned one after the other according to said transverse direction, wherein, in each of said accommodation spaces, the introduction of the first tray is followed by the introduction of at least one second tray which is pushed against said first tray so that said trays advance towards the bottom of said accommodation space along said transverse direction;
extract at least a tray immediately accessible from the respective accommodation space in which it is house.

2. The system according to claim 1, wherein the depth of said accommodation spaces measured according to said transverse direction is equal to twice said length of each of said trays and therefore is the same as the length of two trays which are coplanar with each other when said trays are arranged aligned with each other one after the other within a respective accommodation space.

3. The system according to claim 1, wherein said guide means comprise a plurality of shaped channels that are present on the surfaces facing each other of said walls and that develop according to said transverse direction, the height of each of said shaped channels measured according to said vertical direction being at least the same as the thickness of each of said trays.

4. The system according to claim 1, wherein said movement means comprise at least one Cartesian robot which is arranged inside said accumulation structure and which comprises displacement and gripping means which are configured to perform said insertion and extraction operations of said trays.

5. The system according to claim 1, comprising a computer means in turn comprising memory means in which a computer product is stored which, when it is in the processing step, manages and controls the system.

6. The system according to claim 1, wherein each of said objects is a coil of flexible tape on which electrical/electronic components are removably fixed.

7. A method for the storage and picking in and from said accumulation structure objects arranged on trays that uses the system according to claim 1, wherein:
said method for storage envisages slidingly inserting into said accommodation spaces at least two trays arranged aligned with each other one after the other according to said transverse direction, wherein, in each of said accommodation spaces, the introduction of the first tray is followed by the introduction of at least one second tray which is pushed against said first tray so that said trays advance towards the bottom of said accommodation space along said transverse direction;
said method for picking envisages extracting at least a tray immediately accessible from the respective accommodation space in which it is housed.

8. The method according to claim 7, wherein said method for storage comprises the following operations:
A. picking from said door a first tray for storing it in said accumulation structure;
B. arranging said first tray aligned and coplanar frontally to a chosen accommodation space;
C. inserting said first tray into said chosen accommodation space and advancing said first tray by sliding towards the bottom of said chosen accommodation space according to said transverse direction;
D. picking from said door a second tray to be stored in said accumulation structure;
E. arranging said second tray aligned, coplanar and in contact with said first tray present in said chosen accommodation space;
F. pushing said second tray against said first tray to advance into said chosen accommodation space said first tray and said second tray, both according to said transverse direction and towards the bottom of said chosen accommodation space;
G. repeating said operations D, E and F for any additional tray to be inserted into said accommodation space.

9. The method according to claim 7, wherein said method for picking comprises the following operations:
A. identifying an accommodation space in which the first tray to be picked is received;
B. if the first tray to be picked is immediately accessible, since it is the only one present in said accommodation space or because in said accommodation space there is no second tray preceding it according to said transverse direction in the direction facing the bottom of said accommodation space, extracting said first tray from said accommodation space;
C. if the first tray to be picked is not immediately accessible, since one or more second trays precede it according to said transverse direction in the direction facing the bottom of said accommodation space, extracting each of said one or more second trays from said accommodation space and inserting each of said one or more second trays into a respective auxiliary accommodation space of said accumulation structure;
D. extracting said first tray from said accommodation space.

10. The system according to claim 1, wherein said movement means are configured to:
extract said at least two trays one after the other from the respective accommodation space in which they are housed, wherein the extraction of the first tray, which is the closest to the bottom of said accommodation space, takes place after extracting from said accommodation space at least a second tray preceding said first tray, said at least a second tray being inserted into an auxiliary accommodation space before proceeding to extract said first tray from said accommodation space.

11. A method according to claim 7, wherein said method for picking envisages extracting said at least two trays one after the other from the respective accommodation space in which they are housed, wherein the extraction of the first tray, which is the closest to the bottom of said accommodation space, takes place after extracting from said accommodation space at least one second tray preceding said first tray, said at least one second tray being inserted into an auxiliary accommodation space before proceeding to extract said first tray from said accommodation space.
